(19) United States
(12) Patent Application Publication
(10) Pub. No.: US 2008/0100287 A1
(43) Pub. Date: May 1, 2008

(54) DISC MEDIA TESTING CONTROL SYSTEM

(76) Inventors: Douglas Andrew Peale, San Jose, CA (US); Wafaa A. Abdalla, San Jose, CA (US)

Correspondence Address: Raghunath S. Minisandram;Seagate Technology LLC, Intellectual Property Department, 920 Disc Drive, SV15B1, Scotts Valley, CA, 95066, US

(21) Appl. No.: 11/555,660

(22) Filed: Nov. 1, 2006

(51) Int. Cl. G01R 33/12

(52) U.S. Cl. 324/212

(57) ABSTRACT

Techniques are described in which a hard disc media tester uses busses conforming to a single bus format to connect control components within a control system of the hard disc media tester. A hard disc media tester may include several control components such as a testing control module, a motion interface, a defect analyzer, a write controller, a motion controller, head loaders, and so on. Busses conforming to a single bus format, such as the Universal Serial Bus (USB) or FireWire formats, may facilitate the communication of control messages among each of these control components. Furthermore, the hard disc media tester may include one or more bus hubs to allow many components to be controlled through a single cable.

### TECHNICAL FIELD

The invention relates to computer disc drives, and particularly to testing computer disc drives.

### BACKGROUND

A hard disc drive is composed of one or more spinning platters. Each surface of the platters may hold information in the form of small magnetic charges. An armature bearing read or write heads moves over the surface of the platters to detect the magnetic charges on the platters or to cause some parts of the platters to acquire a certain magnetic charges.

A hard disc media tester is a device that ensures that the spinning platters of a hard disc do not contain unacceptable flaws. For instance, a hard disc media tester may determine whether there are certain spots on the platters that do not properly hold a magnetic charges. In another example, a hard disc media tester may determine whether a platter has surface protrusions, is not sufficiently flat, or otherwise.

Typical hard disc media testers include several control components linked by several busses. Moreover, busses in hard disc media testers are frequently of different formats. For instance, a hard disc media tester may use an Advanced Technology Attachment (ATA) interconnect to link a master control unit to a motion control component. The same hard disc media tester may also use a Small Computer System Interface (SCSI) interconnect to link the master control unit to a control component that analyzes potential disc defects. Other bus types may include General Purpose Interface Bus (GPIB), RS-232, VMEbus, Industry Standard Architecture (ISA), various customized communications schemes, and so on. Each of the different interconnect formats may require different circuitry or programming. This may increase costs to maintain and update the hard disc media tester and may increase the likelihood that the hard disc media tester will malfunction due to a hardware or software error. The fact that several of these bus types are obsolete or approaching obsolescence may further augment these costs.

### SUMMARY

In general, the invention is directed to a hard disc media tester that uses busses conforming to a single bus format to connect control components within the hard disc media tester. A hard disc media tester may include several control components such as a master control unit, a motion interface, a defect analyzer, a write controller, a motion controller, head loaders, and so on. Busses conforming to a single bus format, such as the Universal Serial Bus (USB) or FireWire, may facilitate that communication of control messages among each of these control components. Furthermore, the hard disc media tester may include one or more bus hubs to reduce the amount of cabling needed for communication among the control components.

Using a single bus type to facilitate the communication of control messages may simplify wiring, reduce bulk, stiffness, and number of cables in the hard disc media tester. In addition, limiting the number of bus types between control components may make debugging simpler because bus monitors may be attached to the cables to monitor signals being sent or received by the testing control module.

In one embodiment, an assembly comprises a hard disc media tester to test a hard disc for a defect and a control system to control the hard disc media tester for testing and to receive test data from the hard disc media tester. In this embodiment, the control unit comprises a plurality of control components to control the hard disc media tester and a plurality of control buses to facilitate communication of control messages among the plurality of control components, wherein the control buses conform to a single bus format.

In another embodiment, a method comprises placing the disc on a spindle in a hard disc media tester. The method also comprises sending control messages to control components in a control system of the hard disc media tester to position a component attached to the platform at a radius of the disc. In addition, the method comprises accessing the disc with the component. In this embodiment, the control messages are sent via busses that conform to a single bus format and the component is selected from a group consisting of: a burnish head, a glide head, a read head, and a write head.

The details of one or more embodiments of the invention are set forth in the accompanying drawings and the description below. Other features, objects, and advantages of the invention will be apparent from the description and drawings, and from the claims.

### BRIEF DESCRIPTION OF DRAWINGS

FIG. 1 is a block diagram illustrating a media tester for testing disc media prior to the installation of the disc media in a disc drive.

FIG. 2 is a block diagram illustrating an exemplary control system to control a media tester.

### DETAILED DESCRIPTION

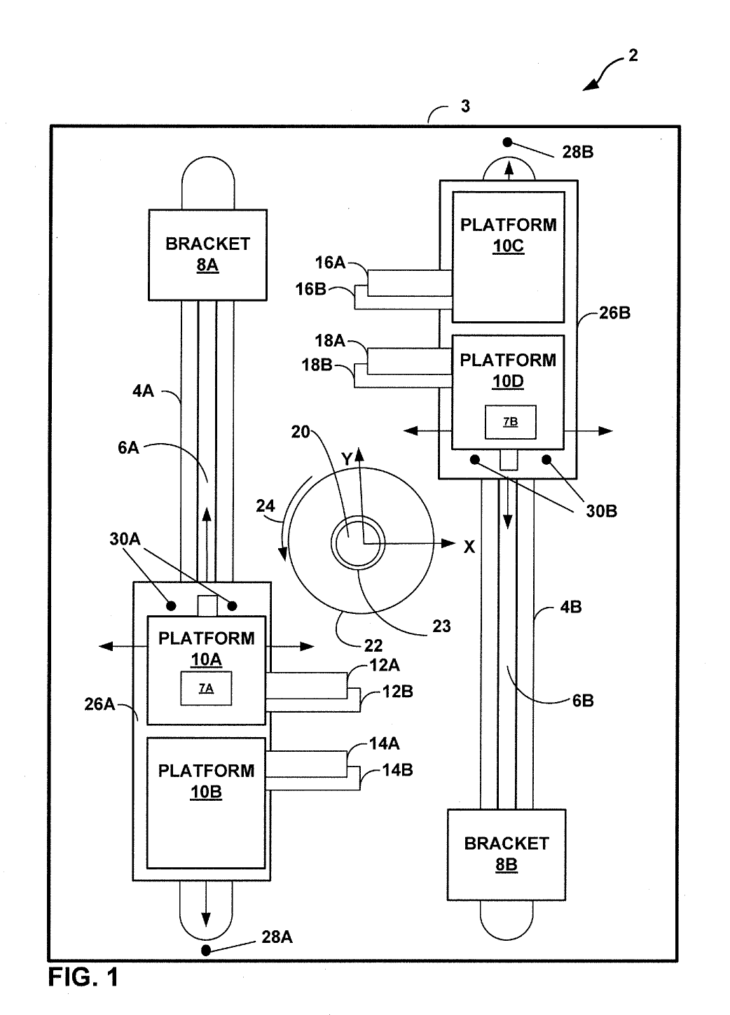

FIG. 1 is a block diagram illustrating a media tester 2 for testing disc media prior to the installation of the disc media in a disc drive. Media tester 2 allows a series of operations to be performed on disc media including, burnishing, glide testing, and spiral certification. Glide testing involves running a glide head, which includes a slider than mimics that of a read/write head in a disc drive over a surface of disc media to detect surface defects. Spiral certification refers to the process of writing a data pattern to the disc, reading the data pattern back, and determining if the data pattern was accurately written to and read from the disc.

Media tester 2 includes a baseplate 3 that includes a mounting surface and provides support for components of media tester 2. Baseplate 3 may be constructed of metal or granite to provide a heavy platform that resists vibration transmission. While granite may be used to construct baseplate 3, baseplate 3 may also be constructed from metal because it may be easier to form recesses precisely in metal than in granite. In one embodiment, baseplate 3 may be constructed of cast aluminum. A layer of nickel may be placed over the aluminum to make the surface more durable and prevent the aluminum from corroding. When baseplate 3 is constructed of aluminum, components of media tester 2 may be electrically grounded to aluminum baseplate 3. When baseplate 3 is constructed of other materials, such as non-metal materials, a copper sheet may be mounted to baseplate 3 to facilitate grounding. In some embodiments, components of media tester 2 are grounded to baseplate 3 using high frequency grounding, and a large surface perimeter is provided for the high frequency grounding. With high frequency grounding, high frequency noise is concentrated on the outside edges of the ground, so a surface with a large perimeter may be advantageous.

Media tester 2 includes a spindle 20 mounted at approximately the center of baseplate 3 and sized to receive disc 22. Disc 22 may be, for example, a magnetic data storage disc. Spindle 20 rotates in order to rotate disc 22 in the direction indicated by arrow 24. Disc 22 has a top surface and a bottom surface, both of which are parallel with baseplate 3 when disc 22 is placed on spindle 20. When disc 22 is placed on spindle 20, the bottom surface is closer to baseplate 3, and the top surface is farther away from baseplate 3.

Baseplate 3 includes recesses 4A and 4B (collectively, “recesses 4”) to accommodate actuators 6A and 6B, respectively. Actuators 6A and 6B (collectively, “actuators 6”) may be mounted in recesses 4A and 4B by brackets 8A and 8B, respectively. Recesses 4 may be formed by using any technique known in the art, e.g., machining or cast molding.

Carriages 26A and 26B (collectively, “carriages 26”) may be affixed to actuators 6A and 6B and be located above recesses 4A and 4B, respectively. Carriage 26A holds platforms 10A and 10B and carriage 26B holds platforms 10C and 10D. Collectively, platforms 10A, 10B, 10C, and 10D may be referred to herein as “platforms 10”. Each of platforms 10 includes a top head and a bottom head. As illustrated in the example of FIG. 1, platform 10A includes top head 12A and bottom head 12B, platform 10B includes top head 14A and bottom head 14B, platform 10C includes top head 16A and bottom head 16B, and platform 10D includes top head 18A and bottom head 18B.

Actuators 6 may move carriages 26 in the y-direction. Because platforms 10A and 10B are attached to carriage 26A, platforms 10A and 10B and their respective heads move along with carriage 26A in the y-direction. Likewise, because platforms 10C and 10D are attached to carriage 26B, platforms 10C and 10D and their respective heads move along with carriage 26B in the y-direction. Thus, by moving carriages 26 in the y-direction, actuators 6 may position any of the heads at any radius of disc 22.

In addition, platform 10A and platform 10D include actuators 7A and 7B (collectively, actuators 7), respectively. Actuators 7 include actuator motors (not shown) and enable platforms 10A and 10D to move independently along the x-axis. Movement along the x-axis may be necessary to prevent heads 12A and 12B and heads 18A and 18B from colliding with spindle 20 when actuators 6 position heads 14A and 14B or heads 16A and 16B at a minimum usable inner diameter 23 of disc 22.

Furthermore, each of platforms 10 include actuators with actuator motors to raise and lower respective top heads onto disc 22. In addition, platforms 10 include actuators with actuator motors to raise and lower respective bottom heads onto disc 22. When the actuators lower top heads onto disc 22 and raise the bottom heads up to disc 22, the top heads and bottom heads may access disc 22. When a top head is not in use, the actuator raises the top head away from disc 22. Similarly, when a bottom head is not in use, the actuator lowers the bottom head away from disc 22.

Top head 12A and bottom head 12B may be used to burnish disc 22 and may be collectively referred to herein as “burnish heads 12.” The process of burnishing disc 22 removes protrusions from the data surfaces of the disc media to reduce surface roughness. To burnish disc 22, actuator 6B moves carriage 26B away from disc 22 and actuator 6A moves carriage 26A toward disc 22. When actuator 6A has moved burnish heads 12A and 12B over and under disc 22 respectively, actuators on platform 10A lower top head 12A and raise bottom head 12B such top head 12A and bottom head 12B access disc 22. When spindle 20 rotates disc 22, burnish heads 12 brush the surfaces of disc 22 to remove protrusions from the surfaces.

Top head 18A and bottom head 18B may be used to perform a glide test on disc 22 and may be referred to herein as “glide heads 18.” To perform a glide test, actuator 6A moves carriage 26A away from disc 22 and actuator 6B moves carriage 26B toward disc 22. When actuator 6B has moved glide heads 118A and 18B over and under disc 22 respectively, actuators on platform 10D lower top head 18A and raise bottom head 18B such that top head 118A and bottom head 18B access with disc 22. When spindle 20 rotates disc 22, glide heads 18 may collide with protrusions on the surfaces of disc 22 that remain after a burnishing process. Glide heads 18 may include piezoelectric crystals to produce small electrical voltages when glide heads 18 collide with the protrusions. Circuitry on platform 10D may amplify these electrical voltages and transmit them to a control system (not shown). The control system may then abort the glide test and initiate a new burnishing process on disc 22.

Top head 14A and bottom head 14B may write data to disc 22 and may be collectively referred to herein as “write heads 14.” Furthermore, top head 16A and bottom head 16B may read data from disc 22 and may be referred to herein as “read heads 16.” Write heads 14 and read heads 16 may be used to perform a spiral certification test on disc 22. To perform a spiral certification test, actuator 7A moves platform 10A away from disc 22 along the x-axis and actuator 7B moves platform 10D away from disc 22 along the x-axis. Actuator 6A may then position carriage 26A such that write heads 14A and 14B are over and under disc 22 respectively. Actuators on platform 10B may then lower head 14A and raise head 14B such that heads 14A and 14B access disc 22. Actuator 6B then positions carriage 26B such that read heads 16 may read a data pattern written by write heads 14 one-half revolution of disc 22 after write heads 14 write the data pattern to disc 22. That is, actuator 6B positions read heads 16 such that read heads 16 are one-half track pitch away from spindle 20 as compared to write heads 14. Track pitch is a measure of how far write heads 14 move along the y-axis per revolution of spindle 20. After actuator 6B so positions carriage 26B, actuators on platform 10C may lower head 16A and raise head 16B such that head 16A and head 16B access disc 22.

While spindle 20 rotates disc 22, write heads 14 write a data pattern to disc 22 and read heads 16 attempt to read the data pattern from disc 22 just written by write heads 14. At the same time, actuator 6A may move carriage 26A toward inner diameter 23 of disc 22. As actuator 6A moves carriage 26A, actuator 6B moves carriage 26B toward inner diameter 23 of disc 22 at the same speed. In this way, write heads 14 write a spiral of data on disc 22 and read heads 16 attempt to read this spiral of data. Circuitry on platform 10C amplifies signals read by read heads 16 send the signals to the control system. The control system may then determine whether read heads 16 read from disc 22 what write heads 14 wrote to disc 22. For instance, the control system may determine that data written to disc 22 was not read by read heads 16. This may indicate that the surface of disc 22 may not be properly holding magnetic charges. If read heads 16 did not read the data that write heads 14 wrote to disc 22, the control system may initiate a new spiral certification test. If, during the new spiral certification test, read heads 16 do not read the data the write heads 14 wrote to disc 22 at the same position, the control system may alert a user that disc 22 contains a defect.

Platforms 10B, 10C, and 10D may also include alignment actuators with actuator motors (not shown) to align their respective top heads with their respective bottom heads. In other words, alignment actuators on platforms 10B, 10C, and 10D move top heads 14A, 16A, and 18A such that top heads 14A, 16A, and 118A are precisely aligned with bottom heads 14B, 16B, and 18B. For example, to align write heads 14, actuator 6A positions carriage 26A such that bottom head 14B detects a track previously written on disc 22. While maintaining the position of carriage 26A, disc 22 may then be flipped over such that the same track is now facing top head 14A. The alignment actuator may then adjust the position of top head 14A until top head 14A detects the track. After write heads 14 are aligned, a new disc may be loaded onto spindle 20 and write heads 14 may write a track to both surfaces of the new disc. Actuator 6B may then move carriage 26B such that bottom read head 16B detects the track. An alignment actuator on platform 10C may then position top read head 16A such that top read head 16A detects the track. At this point read heads 16 are aligned. To align glide heads 18, a disc with a bump at a known radius is placed on spindle 20. Actuator 6B then moves carriage 26B such that bottom glide head 15B collides with the bump. While maintaining the position of carriage 26B, the disc with the bump may then be flipped over and an alignment actuator may position top glide head 18A such that top glide head 18A also collides with the bump. When top glide head 18A collides with the bump, glide heads 18 are aligned. Such an alignment actuator may not be necessary on platform 10A because heads 12A and 12B may used to burnish disc 22 and precise alignment of heads 12A and 12B may not be necessary to burnish disc 22. Rather, burnish heads 12 may be aligned visually.

In other embodiments, two discs may be “sandwiched” together on spindle 20 and one side of both discs may be tested simultaneously. This technique may be particularly suited for single-sided discs.

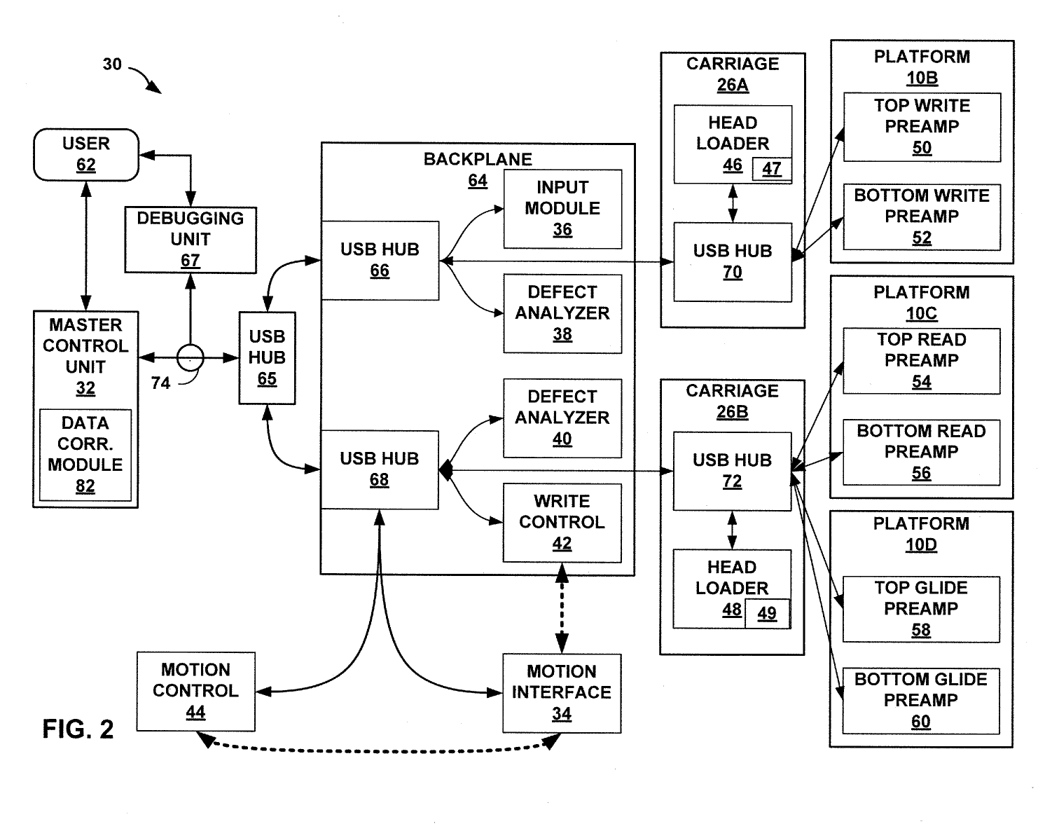

FIG. 2 is a block diagram illustrating an exemplary control system 30 to control media tester 2. Control system 30 includes several control components to control media tester 2. A plurality of Universal Serial Bus (USB) connections acting as control busses facilitate communication of control messages among the control components. In the example of FIG. 2, solid double-ended arrows represent the USB connections. In other embodiments, USB connections may be bus connections conforming to a different high-speed bus format, such as FireWire. The control components of control system 30 may be general-purpose microprocessors, application-specific integrated circuits (ASICs), field-programmable gate arrays (FPGAs), or otherwise.

The control components may include a master control unit 32, a motion interface 34, an input module 36, a first defect analyzer 38, a second defect analyzer 40, a write controller 42, a motion controller 44, a first head loader 46, a second head loader 48, a top write preamp 50, a bottom write preamp 52, a top read preamp 54, a bottom read preamp 56, a top glide preamp 58, and a bottom glide preamp 60. The first head loader 46 may further include a first motor speed control unit 47. The first motor speed control unit 47 permits the control of the speed of the actuator motors. The speed of the actuator motor is selectively variable by program control, by controlling the effective voltage applied to the motor. This can be accomplished by using pulse width modulation that is controlled by a Field Programmable Gate Array (FPGA). The FPGA can include a programmable counter that can be set to vary the on period of the applied voltage and another programmable counter that can be set to vary the off period of the applied voltage. By selectively varying the on period and the off period of the applied voltage, the speed of the actuator motor is controlled. For example, the first motor speed control unit 47 may control the actuator motor that enable precise movement of platform 10A along the x-axis. Additionally, the first motor speed control unit may control the actuator motors that precisely raise and lower top heads 12A and 14A onto disc 22. Additionally, the first motor control unit may control the actuator motor that precisely raise and lower the bottom heads 12B and 14B on to disc 22. Additionally, the first motor speed control unit may control the motor associated with the alignment actuator to precisely align the top head 12A with respect to the bottom head 12B. The second head loader 46 may further include a second motor speed control unit 49. The second motor speed control unit 49 permits the control of the speed of the actuator motors. The speed of the actuator motor is selectively variable by program control, by controlling the voltage applied to the motor. For example, the second motor speed control unit 49 may control the actuator motor that enable precise movement of platform 10D along the x-axis. Additionally, the second motor speed control unit 49 may control the actuator motor that precisely raise and lower top heads 16A and 18A onto disc 22. Additionally, the second motor control unit 49 may control the actuator motor that precisely raise and lower the bottom heads 16B and 18B on to disc 22. Additionally, the second motor speed control unit 49 may control the motor associated with the alignment actuator to precisely align the top head 18A with respect to the bottom head 18B. As illustrated in the example of FIG. 2, a backplane 64 includes a first USB hub 66 and a second USB hub 68. Backplane 64 may be a circuit board physically mounted on media tester 2.

A USB hub 65 relays signals sent between master control unit 32, USB hub 66, and USB hub 68. USB hub 66 relays signals sent between USB hub 65, motion interface 34, input module 36 on backplane 64, defect analyzer 38 on backplane 64, and a USB hub 70 located on carriage 26A. Similarly, USB hub 68 relays signals sent between USB hub 65, defect analyzer 40 on backplane 64, write control 42 on backplane 64, motion control 44, and a USB hub 72 located on a carriage 26B. USB hub 70 relays signals sent between USB hub 66, head loader 46 on carriage 26A, top write preamp 50 on platform 10B, and bottom write preamp 52 on platform 10B. USB hub 72 relays signals sent between USB hub 68, head loader 48 on carriage 26B, top read preamp 54 on platform 10C, bottom read preamp 56 on platform 10C, top glide preamp 58 on platform 10D, and bottom glide preamp 60 on platform 10D.

A user 62 interacts with master control unit 32 to initiate testing. For example, master control unit 32 may present a command line interface or graphical user interface to user 62 through which the user may enter commands. For instance, user 62 may enter a command that instructs master control unit 32 to begin testing. Furthermore, master control unit 32 may present test results to user 62. For example, master control unit 32 may output a test report that indicates which tests media tester 2 performed on disc 22, whether disc 22 successfully passed the tests, and so on. Master control unit 32 may present the test report using a graphical user interface, a web interface, or otherwise. When user 62 interacts with master control unit 32 to initiate a burnish process or a test, such as a glide test or a spiral certification test, master control unit 32 may send one or more control messages to various control components of control system 30 through the USB connections.

To perform a glide test, master control unit 32 may send a control message to motion control 44 to move carriage 26B. Furthermore, master control unit 32 may send a signal to head loader 48 to move glide heads 18 into position. Master control unit 32 may also send signals to top glide preamp 58 and bottom glide preamp 60 to start relaying streams of analog data from glide heads 18A and 18B, respectively. For example, top glide preamp 58 may detect a glide error when the temperature of glide head 18 suddenly increases because glide head 18 collided with a defect protruding from the top surface of disc 22. In another embodiment, glide head 18 may include piezoelectric crystals that produce small electrical voltages when glide head 18 collides with protrusions on the surface of disc 22. When glide errors occur, top glide preamp 58 and bottom glide preamp 60 may amplify these voltages and send them as streams of analog signals to input module 36 via a coaxial cable (not shown). Upon receiving the analog signals, input module 36 may filter the analog signals and send the filtered analog signals to defect analyzer 40 via another coaxial cable (not shown). Defect analyzer 40 may then analyze the filtered analog signals to determine whether the signals indicate the presence of a defect. When defect analyzer 40 detects a defect, defect analyzer 40 may send a control message to master control unit 28 via the USB busses.

To perform a spiral certification test, master control unit 32 may send a control message to motion control 34 to position carriage 26A and a control message to motion control 44 to position carriage 26B. In addition, master control unit 32 may send a control message to head loader 46 to move write heads 14 into position and may send a control message to head loader 48 to move read heads 16 into position. After the movements are made, read head 16 should be 180° from write head 14 on disc 22 at such a distance from the center of disc 22 that read head 16 may read what write head 14 wrote to disc 22 one half revolution of disc 22 ago. Once read head 16 and write head 14 are in position, master control unit 32 may send a control message to write control 42 to begin writing a data pattern to disc 22. When write control 42 receives the control message to begin writing data to disc 22, write control 42 may send control messages to top write preamp 50 and bottom write preamp 52 to write a data pattern to disc 22. Input module 36 may receive streams of analog signals from top read preamp 54 and bottom read preamp 56. Input module 36 may then filter the streams of analog signals and pass the filtered streams of analog signals to defect analyzers 38 and 40 via the coaxial cables. At the same time, motion interface 34 monitors analog encoder signals from spindle 20 and carriages 26. Motion interface 34 transmits these signals to write control 42. Write control 42 filters the analog encoder signals and transmits the filtered signals to defect analyzers 38 and 40 via signals on the backplane (not shown). Defect analyzers 38 and 40 correlate the encoder signals with write and read information to determine whether disc 22 successfully held the data pattern. If disc 22 did not successfully hold the data pattern, defect analyzers 38 and 40 may send control messages to master control unit 28 via the USB busses.

Defect analyzers 38 and 40 may include field-programmable gate arrays (FPGAs) that detect the presence of a defect. However, defect analyzers 38 and 40 may receive analog samples at a rate that is faster than the FPGAs are capable of handling. For example, defect analyzers 38 and 40 may receive analog samples at a frequency of 600 megahertz while the FPGAs in defect analyzers 38 and 40 may only be capable of processing digital data at a rate of 150 megahertz.

To slow the data rate to a rate that the FPGAs are capable of handling, defect analyzers 38 and 40 divide the stream of analog samples at 600 megahertz into four parallel streams of digital samples, each at 150 megahertz. The FPGAs may then process the four parallel streams of digital samples in parallel at 150 MHz to detect defects in disc 22. For example, Analog-to-Digital Converters (ADCs) may receive the stream of analog samples. The ADCs may process the stream of analog samples to simultaneously output two streams of digital samples on two separate busses. The ADCs also output a clock that runs at half the frequency of the analog data. As a result, the digital samples have a slower the data rate. Additional circuitry may divide this clock by two before passing the clock to the FPGAs. After the additional circuitry divides the clock by two, the clock is now a quarter of its original frequency. When running at a quarter of its original frequency, the clock may be referred to herein as the “input clock.” The FPGAs may include registers are clocked on the rising edge of the input clock and the other registers are clocked on the falling edge of the input clock. In this way, each register captures every other sample from the ADCs. The registers that were clocked on the falling edge of the clock have their outputs re-sampled by registers that are clocked with the rising edge of the clock such that all of the registers output data on the rising edge of the input clock (operating at a maximum of 150 MHz) so that there are four parallel digital data streams all clocked on the rising edge of the input clock.

In some embodiments, the FPGAs are capable of processing streams of digital samples at 200 MHz. To utilize this higher processing frequency, a 200 MHz clock may re-clock the data (i.e., four parallel data streams clocked on the rising edge of the input clock). For instance, a 200 MHz clock re-clocks the data with a flag to indicate when samples from the ADCs are in the registers. To reliably re-clock the data, the data is sampled at both the rising edge and the falling edge of the input clock. The outputs of these registers and the input clock are sampled by the 200 MHz clock. Based on the state of the input clock at the time the input clock was sampled, the data captured by the 200 MHz clock that was sampled from the registers that were least recently clocked by the input clock is passed on. This logic ensures that only the data in registers whose clock and data satisfied the registers' set up and hold times are used. The advantages of operating at 200 MHz may include a fixed amount of time between input and output. Furthermore, operating at fixed 200 MHz may require less time between input and output than a variable-frequency clock pipelined approach in which the clock may vary between 10 and 150 MHz.

Control system 30 may also include a bus monitor 74. Bus monitor 74 may monitor control messages on the USB bus from master control unit 32 to USB hub 65. Bus monitor 74 may then forward the control messages on the USB bus to a debugging unit 67 that executes debugging software. Debugging unit 67 may be a personal computer or other type of computing device. In this way, user 62 may access debugging unit 67 to understand what control messages master control unit 32 is sending or receiving. This, in turn, may aid user 62 to debug software or hardware in control system 30.

In control system 30, motion interface 34 may send control messages containing position information along with associated timestamps to data correlation module 82. The position information may describe the motion of carriages 26 and the rotational velocity of spindle 20. Because data correlation module 82 receives position information from motion interface 34 with associated timestamps, data correlation module 82 may accurately record and plot the motion of media tester 2 along all axes of motion. Data correlation module 82 may then display the plot using a graphical user interface. In some embodiments, write control 42 may also send position information and associated timestamps to data correlation module 82.

Plots made by data correlation module 82 may be useful for debugging software and hardware components of control system 80. For example, plots created by data correlation module 82 may be useful in understanding the settling behavior of carriages 26, the speed stability of spindle 20, the delay between the time a control message to move is sent and the time the motion is completed, the accuracy with which motion control 34 maintains a constant linear velocity spiral, and so on. In addition, plots created by data correlation module 82 may be useful in determining how accurately carriage 26B follows a track written by read head 16 on carriage 26A. After generating the plots, data correlation module 82 may provide the plots to debugging software.

Various embodiments of the invention have been described. These and other embodiments are within the scope of the following claims.

1. An assembly comprising:
a hard disc media tester to test a hard disc for a defect using a component; and
a control system to control the hard disc media tester for testing and to receive test data from the hard disc media tester by controlled relative positioning and movement of said component with respect to said hard disc, wherein the control unit comprises:
a plurality of control components to control the hard disc media tester; and
a plurality of control buses to facilitate communication of control messages among the plurality of control components, wherein the control buses conform to a single bus format.

2. The assembly of claim 1, wherein the hard disc media tester comprises:
a baseplate including a mounting surface, wherein the mounting surface includes a recess;
a spindle mounted on the mounting surface of the baseplate;
an actuator mounted to the baseplate and located within the recess; and
a carriage above the recess, wherein the carriage is attached to the actuator such that the actuator is capable of moving said component attached to the carriage to at any radius of a disc placed on the spindle, and
wherein the component is selected from a group consisting of: a burnish head, a glide head, a read head, and a write head.

3. The assembly of claim 2,
wherein the recess is a first recess;
wherein the mounting surface includes a second recess formed by the baseplate; and
wherein the assembly further comprises a second actuator within the second recess.

4. The assembly of claim 3,
wherein the carriage is a first carriage and the component is a first component,
wherein the assembly further comprises:
a second carriage above the second recess; and
a second component attached to the second carriage,
wherein the second component is selected from the group consisting of: a burnish head, a glide head, a read head, a write head, and a read/write head, and
wherein the second carriage is attached to the second actuator such that the second actuator is capable of positioning the second component at any radius of the disc placed on the spindle.

5. The assembly of claim 1, wherein the control busses conform a Universal Serial Bus format.

6. The assembly of claim 1, wherein the control components include a master control unit to initiate testing using the media tester.

7. The assembly of claim 1, wherein the control components include a data correlation unit to create a plot of motions performed by the media tester along an axis of motion.

8. The assembly of claim 7, wherein the data correlation unit provides the plot to debugging software.

9. The assembly of claim 1, wherein the plurality of control components include a defect analyzer to determine whether the disc contains the defect.

10. The assembly of claim 9, wherein the defect analyzer comprises:
an analog-to-digital converter to convert a stream of analog data at a first rate into a plurality of streams of digital data at a second rate, wherein the first rate is faster than the second rate; and
a field-programmable gate array (FPGA) operating at the second rate to process the streams of digital data to determine whether the disc contains defects.

11. The assembly of claim 10,
wherein the analog-to-digital converter outputs two streams of digital data and a clock that is operating at half of the frequency of the first rate;
wherein the FPGA includes a set of registers clocked on a rising edge of the clock and a set of registers clocked on a falling edge of the clock, such that each register captures every other sample in the stream of digital data from the analog-to-digital converter; and
wherein the registers clocked on the rising edge and the registers clocked on the falling edge output data on the rising edge of the clock.

12. The assembly of claim 11, wherein the FPGA operates at a data rate that is faster than a data rate of the output of the registers.

13. A method comprising:
placing a disc on a spindle in a hard disc media tester;
sending control messages to control components in a control system of the hard disc media tester to controllably position a component attached to the platform at a radius of the disc; and
accessing the disc with the component,
wherein the control messages are sent via control busses that conform to a single bus format;
wherein the component is selected from a group consisting of: a burnish head, a glide head, a read head, and a write head.

14. The method of claim 13,
wherein the spindle is mounted on a baseplate; and
wherein the method further comprises:
moving a carriage located above a recess formed by the baseplate toward the disc using an actuator, wherein the actuator is attached to the carriage and positioned within the recess formed by the baseplate.

15. The method of claim 14,
wherein the disc includes a top surface and a bottom surface;
wherein the component is a first component; and
wherein the method further comprises:
moving a second component above a recess formed by the baseplate, wherein the first component accesses the top surface and the first component accesses the bottom surface, wherein the second component is the same one of the group consisting of a burnish head, a glide head, a read head, a write head, and a read/write head as the first component.

16. The method of claim 13, wherein the control busses conform to a Universal Serial Bus format.

17. The method of claim 13, wherein the method further comprises creating a plot of motions performed by the media tester along an axis of motion.

18. The method of claim 13, wherein the method further comprises correlating position information with write and read information to detect a defect in the disc.

19. The method of claim 18, wherein correlating position information comprises:
converting a stream of analog data at a first rate into a stream of digital data at a second rate, wherein the first rate is faster than the second rate; and
processing the digital data with a FPGA to detect the defect, wherein the FPGA operates at a rate slower than the first rate.

20. The method of claim 18,
wherein converting a stream of analog data comprises outputting two streams of digital data and a clock that is operating at half of the frequency of the first rate; and
wherein processing the digital data comprises:
capturing every other sample in the stream of digital data with a first set of registers clocked on a rising edge of the clock;
capturing remaining samples in the stream of digital data with a second set of registers clocked on a falling edge of the clock; and
outputting data from the first set of registers and the second set of registers on the rising edge of the clock.
